(19) United States
(12) Patent Application Publication
(10) Pub. No.: US 2012/0229983 A1
(43) Pub. Date: Sep. 13, 2012

(54) TELEVISION AND ELECTRONIC APPARATUS

(75) Inventor: Yuji NAKAJIMA, Nishitama-gun (JP)

(73) Assignee: KABUSHIKI KAISHA TOSHIBA, Tokyo (JP)

(21) Appl. No.: 13/315,782

(22) Filed: Dec. 9, 2011

(30) Foreign Application Priority Data
Mar. 11, 2011 (JP) 2011-054378

(51) Int. Cl. H05K 7/20

(52) U.S. Cl. 361/697

(57) ABSTRACT

According to one embodiment, an electronic apparatus includes a housing including an opening area and a closing area, a fan in the housing, a first area between the fan and the opening area, a second area between the fan and the closing area, and a windshield in the second area.

### CROSS-REFERENCE TO RELATED APPLICATIONS

This application is based upon and claims the benefit of priority from prior Japanese Patent Application No. 2011-054378, filed Mar. 11, 2011, the entire contents of which are incorporated herein by reference.

### FIELD

Embodiments described herein relate generally to televisions and electronic apparatuses.

### BACKGROUND

Some electronic apparatuses include a heating body, a heat sink, and a fan.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating an electronic apparatus according to a first embodiment;

FIG. 2 is an exemplary cross-sectional view illustrating the electronic apparatus shown in FIG. 1;

FIG. 3 is an exemplary exploded perspective view illustrating a heat sink shown in FIG. 2;

FIG. 4 is an exemplary cross-sectional view schematically illustrating the flow of air in the electronic apparatus shown in FIG. 2;

FIG. 5 is an exemplary perspective view illustrating the cross section of a portion of the internal structure of an electronic apparatus according to a second embodiment;

FIG. 6 is an exemplary perspective view illustrating the cross section of a portion of the internal structure of the electronic apparatus shown in FIG. 5, as viewed from another direction;

FIG. 7 is an exemplary cross-sectional view illustrating the electronic apparatus shown in FIG. 5;

FIG. 8 is an exemplary perspective view illustrating the cross section of a portion of the internal structure of an electronic apparatus according to a third embodiment;

FIG. 9 is an exemplary perspective view illustrating the cross section of a portion of the internal structure of an electronic apparatus according to a fourth embodiment;

FIG. 10 is an exemplary cross-sectional view illustrating an electronic apparatus according to a fifth embodiment;

FIG. 11 is an exemplary cross-sectional view illustrating an electronic apparatus according to a sixth embodiment;

FIG. 12 is an exemplary cross-sectional view illustrating an electronic apparatus according to a seventh embodiment;

FIG. 13 is an exemplary cross-sectional view illustrating an electronic apparatus according to an eighth embodiment; and

FIG. 14 is an exemplary cross-sectional view illustrating a television according to a ninth embodiment.

### DETAILED DESCRIPTION

Various embodiments will be described hereinafter with reference to the accompanying drawings.

In general, according to one embodiment, an electronic apparatus comprises a housing comprising an opening area and a closing area, a fan in the housing, a first area between the fan and the opening area, a second area between the fan and the closing area, and a windshield in the second area.

Hereinafter, exemplary embodiments will be described with reference to the accompanying drawings.

### First Embodiment

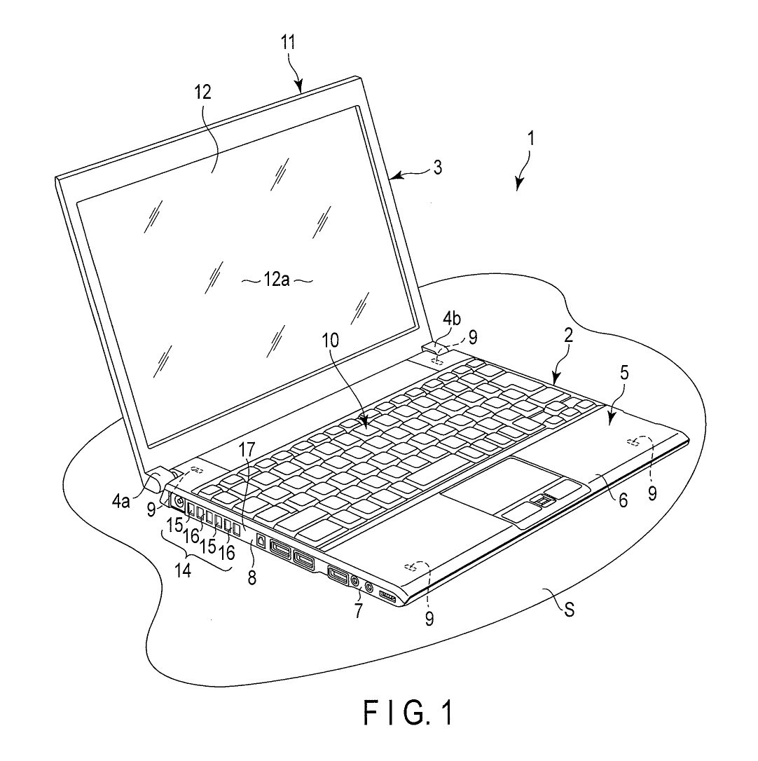

FIGS. 1 to 4 show an electronic apparatus 1 according to a first embodiment. The electronic apparatus 1 is, for example, a notebook portable computer (notebook PC). However, electronic apparatuses to which this embodiment can be applied are not limited thereto. This embodiment can be widely applied to various kinds of electronic apparatuses including, for example, a television, a mobile phone, a smart phone, an electronic book terminal, and a game machine.

As shown in FIG. 1, the electronic apparatus 1 includes a first unit 2, a second unit 3, and hinges 4a and 4b. The first unit 2 is, for example, a main unit provided with a main board. The first unit 2 includes a first housing 5. The first housing 5 is made of a metal material, such as a magnesium alloy. The first housing 5 has a flat box shape including an upper wall 6, a lower wall 7, and a circumferential wall 8.

The lower wall 7 faces a desk surface S when the electronic apparatus 1 is placed on a desk. For example, a plurality of leg portions 9 that comes into contact with the desk surface S is provided on the lower wall 7. The upper wall 6 is opposite to the lower wall 7 with a space therebetween and extends substantially in parallel to the lower wall 7. An input portion 10 (i.e., input receiving portion) is provided on the upper wall 6. An example of the input portion 10 is a keyboard. The input portion 10 is not limited to the keyboard, but may be a touch panel or other input devices.

The circumferential wall 8 connects the edge portion of the lower wall 7 and the edge portion of the upper wall 6. Both or one of the lower wall 7 and the upper wall 6 may be bent toward the circumferential wall 8 and may be connected to the circumferential wall 8 substantially in an arc shape.

As shown in FIG. 1, the second unit 3 is, for example, a display unit and includes a second housing 11 and a display device 12 provided in the second housing 11. The display device 12 is, for example, a liquid crystal display, but is not limited thereto. The display device 12 includes a display screen 12a on which an image or a video is displayed.

The second housing 11 is rotatably (openably) connected to the first housing 5 by the hinges 4a and 4b. In this way, the second unit 3 can be rotated between a first position where the first unit 2 and the second unit 3 overlap each other and a second position where the first unit 2 is opened from the second unit 3. At the second position, the input portion 10 of the first unit 2 and the display screen 12a of the second unit 3 are exposed to the outside of the electronic apparatus 1.

Next, the cooling structure of the electronic apparatus 1 will be described. For convenience of explanation, hereinafter, the “first housing 5” is simply referred to as the “housing 5”.

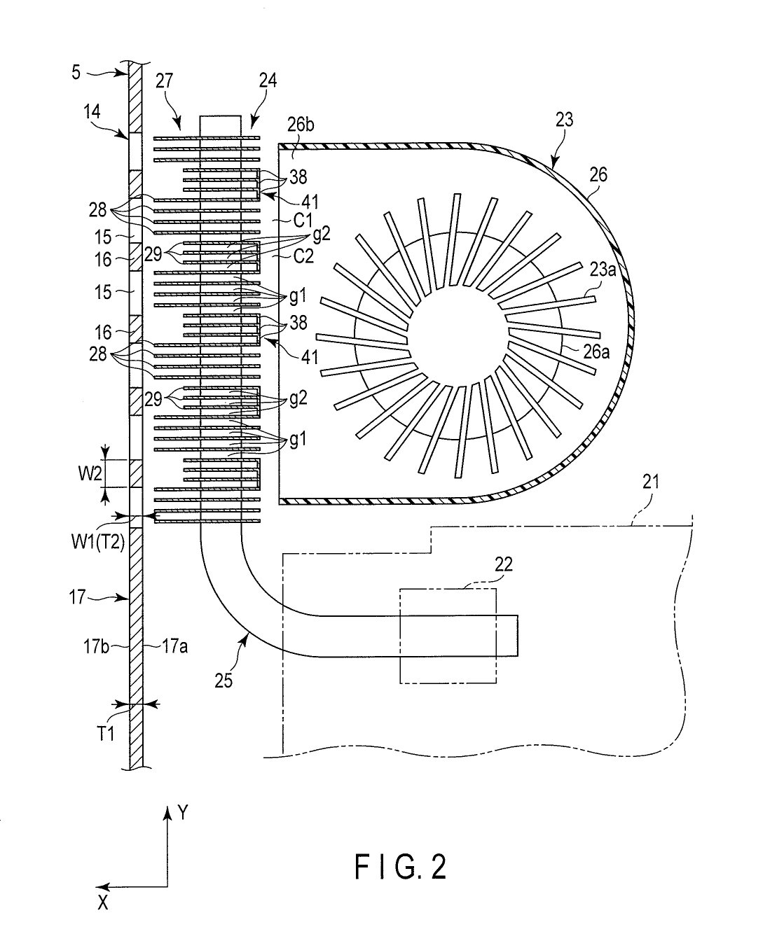

As shown in FIGS. 1 and 2, an outlet portion 14 is provided in the circumferential wall 8 of the housing 5. The position where the outlet portion 14 is provided is not limited to the circumferential wall 8. For example, the outlet portion 14 may be provided in the lower wall 7 or other portions. The outlet portion 14 includes a plurality of opening portions 15 and a plurality of closing portions 16 (blocking portions). The opening portions 15 and the closing portions 16 are alternately provided.

The housing 5 includes an outer wall 17 exposed to the outside. The outer wall 17 is an example of a “wall”. The opening portion 15 is, for example, a through hole provided in the outer wall 17 and is exposed to the outside of the housing 5. The closing portion 16 is, for example, a portion of the outer wall 17 that remains between the opening portions 15 and covers (blocks) an area between the opening portions 15. An example of the closing portion 16 is, for example, a beam (vertical grid) that partitions a plurality of opening portions 15.

A heat sink is provided adjacent to the outlet portion 14 in the housing 5, which will be described below. For example, the grid is provided such that the user does not directly touch the hot heat sink. An example of an “opening area” is a portion (i.e., region) of the housing 5 in which the opening portion 15 is provided. An example of a “closing area” is a portion (i.e., region) of the housing 5 in which the closing portion 16 is provided.

As shown in FIG. 2, the outer wall 17 includes an inner surface 17a (first surface) exposed to the inside of the housing 5 and an outer surface 17b (second surface) exposed to the outside of the housing 5. The distance between the inner surface 17a and the outer surface 17b of the outer wall 17 is a thickness T1. In this embodiment, the thickness T2 of the closing portion 16 is substantially equal to the thickness T1 of the outer wall 17.

For convenience of explanation, a first direction X and a second direction Y are defined. The first direction X is the flow direction of cooling air from a fan, which will be described below, and is substantially perpendicular to the outer wall 17. The second direction Y is substantially parallel to the outer wall 17 and is substantially perpendicular to the first direction X. In this embodiment, the width W1 (that is, the thickness T2 of the closing portion 16) of the closing portion 16 in the first direction X is less than the width W2 of the closing portion 16 in the second direction Y.

As shown in FIG. 2, a circuit board 21 is provided in the housing 5. The circuit board 21 is, for example, a main board, but is not limited thereto. A heating body 22 (i.e., heat-generating component) is mounted on the circuit board 21. The heating body 22 is an electronic component that generates heat during the use of the electronic apparatus 1. An example of the heating body 22 is, for example, a CPU, but the heating body 22 is not limited thereto. For example, other electronic components, such as Northbridge (trademark) and a graphic chip, may be appropriately used as the heating body 22.

A fan 23, a heat sink 24, and a heat pipe 25 are provided in the housing 5. The fan 23 is, for example, a centrifugal cooling fan, but is not limited thereto. Other types of fans may be used as the fan 23. The fan 23 includes a fan case 26 and an impeller 23a that is rotated in the fan case 26. The fan case 26 is provided with inlets 26a and a discharge hole 26b. The fan 23 draws air in the housing 5 from the inlets 26a and discharges the air from the discharge hole 26b.

As shown in FIG. 2, in this embodiment, the fan 23 faces the heat sink 24 and the outlet portion 14. The position where the fan 23 is provided is not limited thereto. For example, the fan 23 may be provided so as to be separated from the heat sink 24 and the outlet portion 14 and discharge air in a direction different from the direction in which the heat sink 24 and the outlet portion 14 face each other. In the fan 23 arranged in this way, the flow direction of the air discharged from the fan 23 is changed such that the air flows toward the heat sink 24 and the outlet portion 14 while the air flows in the housing 5, and the air passes through the heat sink 24 and is then exhausted from the outlet portion 14 to the outside of the housing 5.

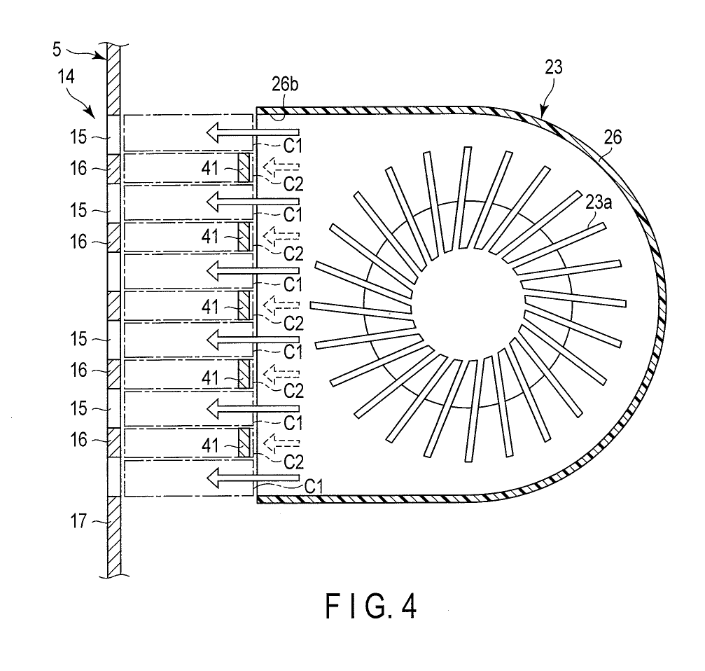

As schematically shown in FIG. 4, a plurality of first areas C1 and a plurality of second areas C2 are provided between the fan 23 and the outlet portion 14. The first area C1 is a first flow path (first cooling air path) that is provided so as to correspond to the opening portion 15 and is from the fan 23 to the opening portion 15. The second area C2 is a second flow path (second cooling air path) that is provided so as to correspond to the closing portion 16 and is from the fan 23 to the closing portion 16. As shown in FIG. 4, for example, the first and second areas C1 and C2 are alternately arranged.

The first area C1 and the second area C2 are not physically partitioned in the housing 5. An example of the first area C1 is an area from the fan 23 to the opening portion 15 (that is, an area between the fan 23 and the opening portion 15). An example of the second area C2 is an area from the fan 23 to the closing portion 16 (that is, an area between the fan 23 and the closing portion 16).

As shown in FIG. 2, the heat sink 24 is provided between the fan 23 and the outlet portion 14. For example, the heat sink 24 is arranged close to the outlet portion 14 and is adjacent to the outlet portion 14. The heat sink 24 is arranged substantially in parallel to the outer wall 17 of the housing 5 and faces the plurality of opening portions 15 and the plurality of closing portions 16. The heat pipe 25 is provided between the heat sink 24 and the heating body 22. The heat sink 24 is thermally connected to the heating body 22 through the heat pipe 25.

Next, the heat sink 24 will be described.

In this embodiment, the heat sink 24 includes a plurality of fins 27 thermally connected to the heating body 22. As shown in FIG. 2, the plurality of fins 27 includes a plurality of first fins 28 provided in the first area C1 and a plurality of second fins 29 provided in the second area C2. The first fins 28 are provided so as to correspond to the opening portion 15 and are adjacent to (for example, face) the opening portion 15 in the first direction X. The second fins 29 are provided so as to correspond to the closing portion 16 and are adjacent to (for example, face) the closing portion 16 in the first direction X.

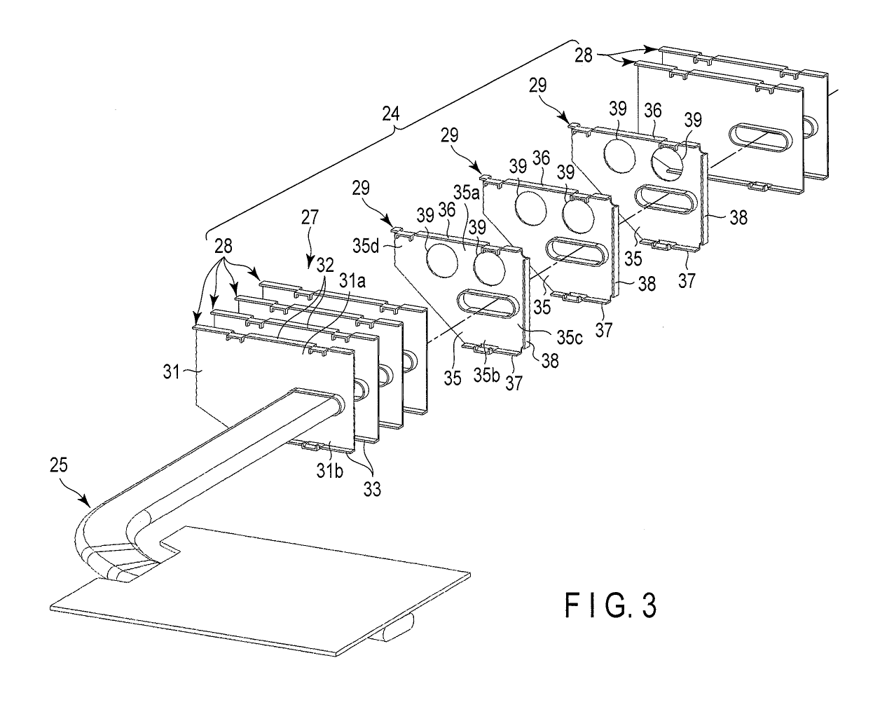

FIG. 3 is an exploded view illustrating the heat sink 24. As shown in FIG. 3, the first fin 28 is, for example, a standard fin. The second fin 29 is, for example, a special fin and has an outward shape different from that of the first fin 28. In this embodiment, the second fin 29 has a shape for blocking air in an air intake side of the heat sink 24.

Specifically, the first fin 28 includes a main portion 31 (first portion), a first bent portion 32 (second portion), and a second bent portion 33 (third portion). The main portion 31 has a plate shape that is substantially perpendicular to the heat pipe 25 and the heat pipe 25 passes through the main portion 31. No hole is formed in the main portion 31 of the first fin 28.

The main portion 31 includes a first end portion 31a (for example, an upper end portion) and a second end portion 31b (for example, a lower end portion) that is disposed opposite to the first end portion 31a. The first bent portion 32 is bent from the first end portion 31a of the main portion 31 substantially in the horizontal direction and extends substantially in parallel to the heat pipe 25. The second bent portion 33 is bent from the second end portion 31b of the main portion 31 substantially in the horizontal direction and extends substantially in parallel to the heat pipe 25. The first and second bent portions 32 and 33 come into contact with a neighboring fin 27 and define a gap between the fins 27.

As shown in FIG. 3, the second fin 29 includes a main portion 35 (first portion), a first bent portion 36 (second portion), a second bent portion 37 (third portion), and a third bent portion 38 (fourth portion). The main portion 35 has a plate shape that is substantially perpendicular to the heat pipe 25 and the heat pipe 25 passes through the main portion 35. As shown in FIGS. 2 and 3, the size of the main portion 35 of the second fin 29 is less than that of the main portion 35 of the first fin 28 and the main portion 35 includes, for example, a plurality of holes 39 formed therein.

In this way, the area (heat dissipation area) of the second fin 29 is less than that of the first fin 28 and has a heat dissipation performance less than that of the first fin 28. The second fin 29 may have substantially the same area and heat dissipation performance as the first fin 28.

The main portion 35 of the second fin 29 includes a first end portion 35a (for example, an upper end portion) and a second end portion 35b (for example, a lower end portion) disposed opposite to the first end portion 35a.

The first bent portion 36 is bent from the first end portion 35a of the main portion 35 substantially in the horizontal direction and extends substantially in parallel to the heat pipe 25. The second bent portion 37 is bent from the second end portion 35b of the main portion 35 substantially in the horizontal direction and extends substantially in parallel to the heat pipe 25. The first and second bent portions 36 and 37 come into contact with a neighboring fin 27 and define the gap between the fins 27.

The main portion 35 further includes a third end portion 35c that extends between the edge portion of the first end portion 35a and the edge portion of the second end portion 35b and a fourth end portion 35d disposed opposite to the third end portion 35c. The third end portion 35c faces the discharge hole 26b of the fan 23. The fourth end portion 35d is adjacent to the outlet portion 14.

That is, the third end portion 35c is an upstream end portion and the fourth end portion 35d is a downstream end portion in the flow direction (first direction X) of cooling air from the fan 23. The third end portion 35c is an example of the “first end portion” of the second fin 29 from another point of view. The fourth end portion 35d is an example of the “second end portion” of the second fin 29 from another point of view.

The third bent portion 38 forms a portion of a wall portion 41 (i.e., wall) with which cooling air collides. The wall portion 41 is an example of a “windshield portion” (i.e., windbreak portion) and is an example of a “portion configured to guide at least a portion of the cooling air flowing toward the closing portion 16 into the first area C1”. The third bent portion 38 is bent (folded) from the third end portion 35c of the main portion 35 in a direction that is substantially perpendicular to the main portion 35 and extends substantially in parallel to the heat pipe 25. In other words, in this embodiment, the wall portion 41 is formed by bending the end portions of the second fins 29. The third bent portion 38 extends in a direction crossing (for example, a direction substantially perpendicular to) the flow direction (first direction X) of the cooling air.

The third bent portion 38 comes into contact with a neighboring fin 27 and blocks the gap between the fin 27 provided with the third bent portion 38 and a neighboring fin 27. In this embodiment, the third bent portion 38 blocks the entire gap between the fins 27, but the embodiment is not limited thereto. The third bent portion 38 may block at least a portion of the gap.

As described above, as shown in FIG. 2, a plurality of fins 27 in the heat sink 24 defines a first gap g1 therebetween and a second gap g2 therebetween. At least one side of the first gap g1 is defined by, for example, the first fin 28. At least one side of the second gap g2 is defined by, for example, the second fin 29.

The first gap g1 faces the opening portion 15 in the flow direction (first direction X) of the cooling air. The second gap g2 faces the closing portion 16 in the flow direction (first direction X) of the cooling air. That is, the cooling air flowing through the first gap g1 is exhausted from the opening portion 15 to the outside of the housing 5. The cooling air flowing through the second gap g2 may collide with the closing portion 16 without the third bending portion 38. The first gap g1 is disposed in the first area C1. The second gap g2 is disposed in the second area C2.

As shown in FIGS. 2 and 4, in this embodiment, for example, the third bent portion 38 of the second fins 29 form the wall portion 41 which blocks the second gap g2. The wall portion 41 is provided in each of the plurality of second areas C2 and blocks a plurality of second gaps g2. The wall portion 41 causes the second area C2 and the first area C1 to have different structures.

In this way, at least a portion of the cooling air flowing from the fan 23 to the closing portion 16 collides with the wall portion 41. The flow direction of at least a portion of the cooling air colliding with the wall portion 41 is changed from a direction toward the closing portion 16 to a direction toward the first area C1. That is, at least a portion of the cooling air collides with the wall portion 41 and the flow direction thereof is changed such that the cooling air flows into the first area C1. The cooling air passes through the first area (that is, the first gap g1) and is exhausted from the opening portion 15 to the outside of the housing 5 without substantially colliding with the closing portion 16.

Next, the operation of the electronic apparatus 1 will be described.

As shown in FIG. 2, the cooling air flowing from the fan 23 to the opening portion 15 passes through the first gap g1 of the heat sink 24. Then, the cooling air draws heat from the fin 27 while passing through the first gap g1, is heated, and is then exhausted from the opening portion 15 to the outside of the housing 5.

As shown in FIGS. 2 and 4, in this embodiment, the wall portion 41 is provided in the second area C2 by a portion of the heat sink 24. That is, the wall portion 41 is provided so as to correspond to the closing portion 16. Therefore, at least a portion of the cooling air flowing from the fan 23 to the closing portion 16 collides with the wall portion 41 and changes its flowing direction to flow into the first gap g1 without flowing into the second gap g2 of the heat sink 24. Then, the cooling air draws heat from the fin 27 while passing through the first gap g1, is heated, and is then exhausted from the opening portion 15 to the outside of the housing 5. Therefore, the heated air does not substantially collide with the closing portion 16 and the temperature of the closing portion 16 is less likely to increase. When an increase in the temperature of the closing portion 16 can be suppressed, it is possible to suppress an increase in the temperature of the housing 5.

According to the electronic apparatus 1 having the above-mentioned structure, it is possible to suppress an increase in the temperature of the housing 5.

For comparison, an electronic apparatus that does not include the wall portion 41 (third bent portion 38) is considered. In this case, air from the fan draws heat while passing through a space between the fins of the heat sink and is then heated. A portion of the heated air passes through the heat sink 24 and collides with the closing portion (grid) of the housing 5. In this way, the temperature of the closing portion increases. When the temperature of the closing portion increases, the temperature of another portion (for example, a palm rest) of the housing also increases through the housing surface. When the increasing rate of the temperature of the housing is high, the user is likely to feel discomfort.

Therefore, the electronic apparatus 1 according to this embodiment includes the housings 5 provided with the opening portions 15 and the closing portions 16, the fan 23 provided in the housing 5, and the wall portion 41 (i.e., windshield portion) that is provided in the second area C2 such that the first area C1 extending from the fan 23 to the opening portion 15 is different from the second area C2 extending from the fan 23 to the closing portion 16. Since the wall portion 41 is provided, the heated air is less likely to flow to the closing portion 16 and the heated air does not collide with the closing portion 16. Therefore, it is possible to suppress an increase in the temperature of the closing portion 16 and thus suppress an increase in the temperature of the housing 5.

In this embodiment, the electronic apparatus includes the housing 5 in which the opening portions 15 and the closing portions 16 are alternately arranged, the heat sink 24 that faces the opening portions 15 and the closing portions 16 and is thermally connected to the heating body 22, and the wall portions 41 that are provided in the plurality of second areas C2 and change the flow direction of at least a portion of the cooling air flowing toward the closing portions 16 such that the cooling air flows toward the first areas C1.

According to this structure, at least a portion of the cooling air blocked by the wall portion 41 flows into the first area C1 and is then exhausted from the opening portion 15 to the outside of the housing 5. Therefore, the heated air is less likely to collide with the closing portion 16 and it is possible to suppress an increase in the temperature of the housing 5.

In this embodiment, at least a portion of the wall portion 41 extends in a direction that intersects the flow direction of the cooling air. According to this structure, it is possible to reliably change the flow direction of the cooling air to the closing portion 16 and thus suppress an increase in the temperature of the housing 5.

In this embodiment, the wall portion 41 blocks at least a portion of the gap g2 between the fins 27 of the heat sink 24. According to this structure, it is possible to reliably reduce the amount of cooling air flowing to the closing portion 16 and thus suppress an increase in the temperature of the housing 5.

In this embodiment, the wall portion 41 is formed by bending the end portions of the fins 27 of the heat sink 24. According to this structure, it is possible to achieve a structure including the wall portion 41 without additionally providing a special member. In addition, in this embodiment, the bent portion 38 is provided in the upstream end portion (third end portion 35c) of the fin 27. However, instead of this structure, the bent portion may be provided in the downstream end portion (fourth end portion 35d) of the fin 27. It is preferable that the bent portion 38 be provided in the upstream end portion of the fin 27 in order to improve the heat dissipation performance since air heated by the heat sink 24 is less likely to remain in the housing 5.

In this embodiment, the heat sink 24 includes the first fin 28 that is provided in the first area C1 and the second fin 29 that is provided in the second area C2. The area (heat dissipation area) of the second fin 29 is less than that of the first fin 28. According to this structure, the heat dissipation performance of the second fin 29 is less than that of the first fin 28 and air in the vicinity of the second fin 29 is less likely to be heated. Therefore, the cooling air that is leaked from the wall portion 41 and then flows to the second area C2 is less likely to be heated by the second fin 29. Therefore, the cooling air that is leaked from the wall portion 41 and then flows to the second area C2 is not heated to a sufficiently high temperature and collides with the closing portion 16. As a result, it is possible to suppress an increase in the temperature of the closing portion 16 and thus suppress an increase in the temperature of the housing 5.

Next, a pressure gradient in the housing 5 will be described.

First, for comparison, an electronic apparatus that does not include the wall portion 41 will be described. In this case, when the pressure between the fan and the heat sink is P₁, the pressure between the heat sink and the outlet portion is P₂, and the external pressure of the housing is P₀, the relationship P₁>P₂>P₀ is established. The reason is as follows. A portion of the air passing through the heat sink collides with the closing portion and air stagnates before the closing portion 16. As a result, the pressure P₂ is higher than the pressure P₀.

On the other hand, an electronic apparatus including the wall portion 41 is considered. When the pressure between the fan and the heat sink is P₁, the pressure between the heat sink and the outlet portion is P₂, and the external pressure of the housing is P₀, the relationship P₁>P₂≈P₀ is established. The reason is that air passing through the heat sink is less likely to collide with the closing portion and P₂ is approximate to P₀.

It is important that the value of P₁ and the value of P₀ be determined by the performance of the fan and atmospheric pressure, regardless of whether the wall portion 41 is provided. Therefore, when the same fan is used, the difference (pressure gradient) between P₁ and P₂ in the electronic apparatus including the wall portion 41 is more than the difference (pressure gradient) between P₁ and P₂ in the electronic apparatus that does not include the wall portion 41. This means that cooling air is likely to flow through the heat sink and can draw a large amount of heat from the heat sink in the electronic apparatus including the wall portion 41. That is, the wall portion 41 makes it possible to improve the cooling performance of the electronic apparatus 1.

### Second Embodiment

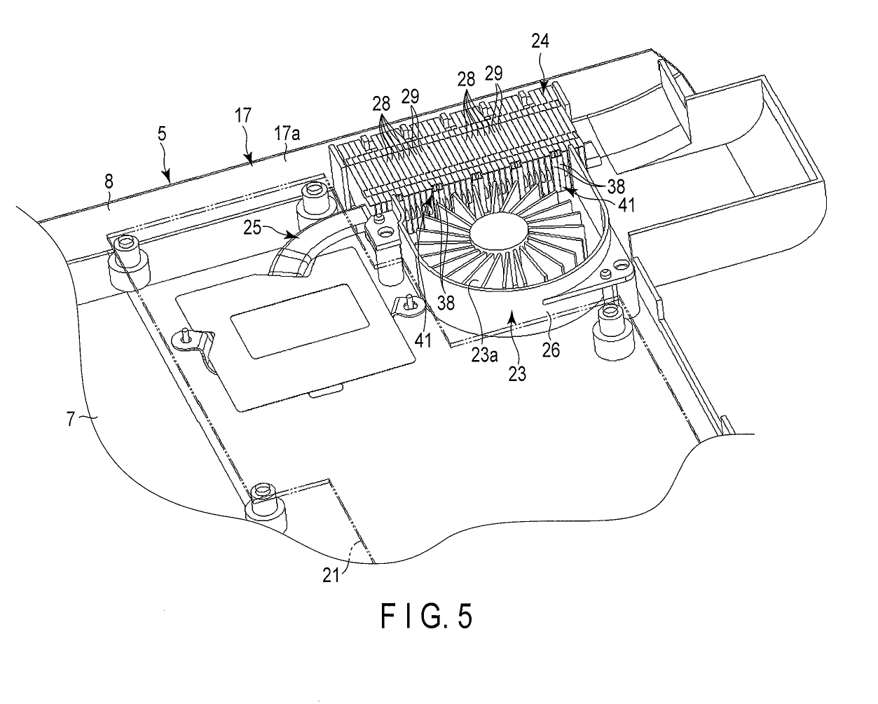

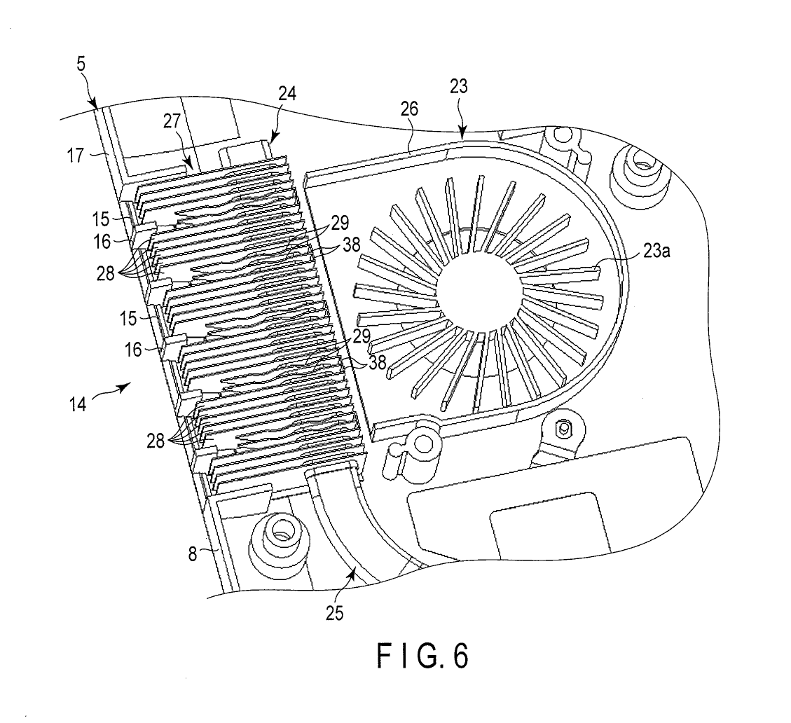

Next, an electronic apparatus 1 according to a second embodiment will be described with reference to FIGS. 5 to 7. In the second embodiment, components having the same or similar functions as those in the first embodiment are denoted by the same reference numerals and a description thereof will not be repeated. In addition, structures other than the following structures are the same as those in the first embodiment.

As shown in FIGS. 5 to 7, the length of a second fin 29 is less than that of a first fin 28 in the flow direction (first direction X) of cooling air. The upstream end portion of the first fin 28 and the upstream end portion of the second fin 29 are aligned substantially at the same position. Therefore, the downstream end portion of the second fin 29 is farther away from an inner surface 17a of an outer wall 17 of a housing 5 than the downstream end portion of the first fin 28. That is, in a heat sink 24, the second fin 29 is smaller than the first fin 28 and a recess portion 45 is provided so as to face a closing portion 16.

As shown in FIGS. 5 to 7, in this embodiment, the closing portion 16 extends at an angle of about 90 degrees with respect to the outer wall 17 of the housing 5. That is, the closing portion 16 extends in a direction (first direction X) substantially perpendicular to the outer wall 17. The closing portion 16 protrudes from the opening portion 15 to the inside of the housing 5. That is, the closing portion 16 protrudes from the inner surface 17a of the outer wall 17 to the inside of the housing 5.

The closing portion 16 includes a first portion 16a that is adjacent to the opening portion 15 and a second portion 16b that is disposed inside compared to the opening portion 15 in the housing 5. The second portion 16b is a rib that is provided as a portion of the closing portion 16 in the housing 5, from another point of view. For example, the second portion 16b is connected to at least one of the upper wall 6 and the lower wall 7 of the housing 5 and is supported by the upper wall 6 or the lower wall 7.

The closing portion 16 extends from the outer wall 17 of the housing 5 to the recess portion 45 of the heat sink 24. A portion of the closing portion 16 extends into the recess portion 45 (that is, into an area of the heat sink 24). That is, a portion of the closing portion 16 extends into the gap between the fins 27. In other words, a portion of the closing portion 16 faces the first fin 28 in a direction (second direction Y) that is substantially parallel to the outer wall 17.

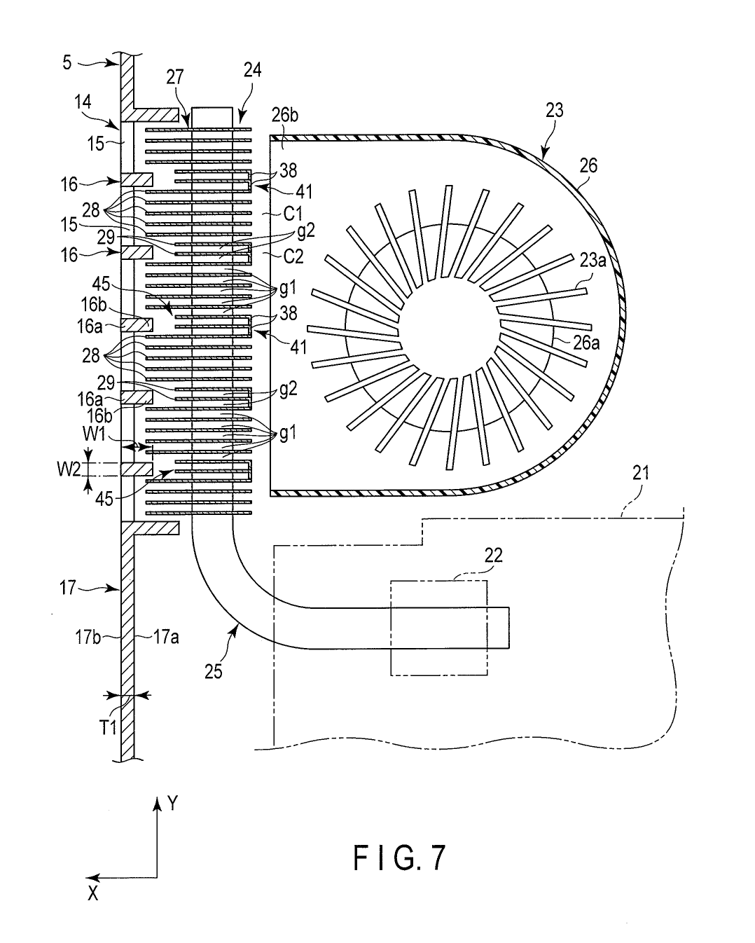

As shown in FIG. 7, the width W1 of the closing portion 16 in the first direction X is larger than the width W2 of the closing portion 16 in the second direction Y. The width W2 of the closing portion 16 in the second direction Y is substantially equal to, for example, the thickness T1 of the outer wall 17 of the housing 5. For example, the width W2 of the closing portion 16 in the second direction Y is about 1 mm. For example, the width W1 of the closing portion 16 in the first direction X is about 2 mm to 3 mm.

That is, in this embodiment, the closing portion 16 has a small width and is elongated in the depth direction. Therefore, for example, it is possible to increase the size of the opening portion 15, as compared to the first embodiment. For example, it is possible to reduce the size of the second area C2 and increase the size of the first area C1, as compared to the first embodiment. In this embodiment, for one opening portion 15, the number of second fins 29 is reduced by one and the number of first fins 28 is increased by one, as compared to the first embodiment. Therefore, the heat sink 24 according to this embodiment has a heat dissipation performance more than that of the heat sink according to the first embodiment.

According to the electronic apparatus 1 having the above-mentioned structure, it is possible to suppress an increase in the temperature of the housing 5, similarly to the first embodiment.

In addition, in this embodiment, the width W1 of the closing portion 16 in the flow direction (first direction X) of the cooling air is more than the width W2 thereof in a direction (second direction Y) substantially perpendicular to the flow direction of the cooling air. Therefore, as viewed from the fan 23, the area of the closing portion 16 that blocks the flow of air is small and the heated air is less likely to collide with the closing portion 16. As a result, an increase in the temperature of the housing 5 is suppressed.

In this embodiment, the closing portion 16 extends from the opening portion 15 to the inside of the housing 5. Therefore, even when the width W2 of the closing portion 16 in a direction (second direction Y) substantially perpendicular to the flow direction of the cooling air is reduced a little, it is possible to ensure the sufficient strength of the closing portion 16 serving as a grid. In this way, it is possible to ensure the sufficient strength of the housing 5 in the structure in which the flow of air is less likely to be hindered.

In this embodiment, in the heat sink 24, the second fin 29 is smaller than the first fin 28 and the recess portion 45 is provided so as to face the closing portion 16. The closing portion 16 extends to the recess portion 45 of the heat sink 24 and a portion of the closing portion 16 is inserted into the recess portion 45. That is, a dead space in the housing 5 which is caused by the second fin 29 smaller than the first fin 28 is effectively used and the closing portion 16 extends to the dead space. In this way, even when the closing portion 16 protrudes toward the inside of the housing 5, it is not necessary to increase the size of the housing 5. That is, according to the electronic apparatus 1 having the above-mentioned structure, it is possible to mount components with high density and reduce the size of the electronic apparatus 1.

### Third Embodiment

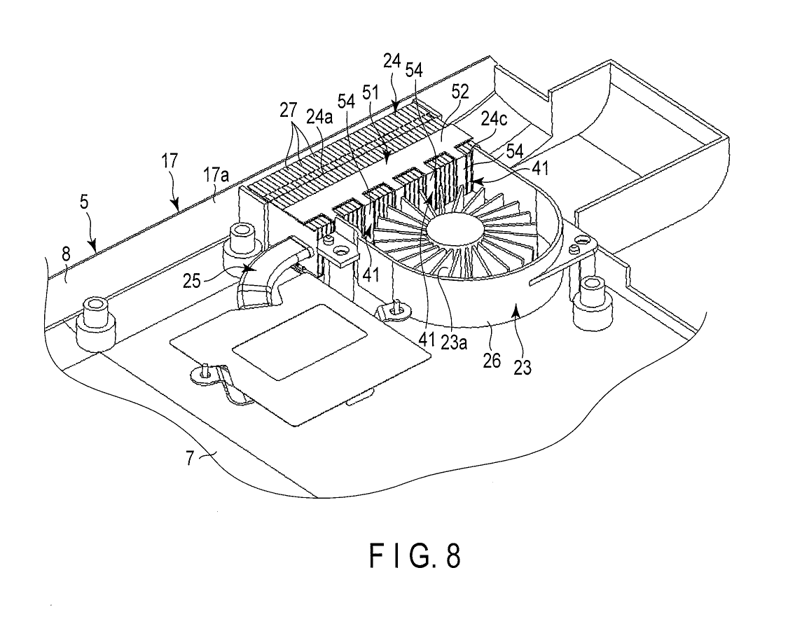

Next, an electronic apparatus 1 according to a third embodiment will be described with reference to FIG. 8. In the third embodiment, components having the same or similar functions as those in the first and second embodiments are denoted by the same reference numerals and a description thereof will not be repeated. In addition, structures other than the following structures are the same as those in the first embodiment.

As shown in FIG. 8, a heat sink 24 according to this embodiment does not include a second fin 29. The heat sink 24 includes one kind of fins 27 arranged in parallel to each other. That is, in this embodiment, the heat sink 24 does not include the third bent portion 38 (wall portion 41). The heat sink 24 may include a second fin 29 that has an area smaller than that of the first fin 28 and is disposed at a position corresponding to a closing portion 16.

As shown in FIG. 8, in this embodiment, a film member 51 is attached to the heat sink 24. The film member 51 is, for example, an insulator and is made of a plastic material. The film member 51 is fixed to the heat sink 24 by, for example, a double-sided tape and is then provided in a housing 5.

The heat sink 24 includes a first surface 24a that faces an upper wall 6 of the housing 5, a second surface that faces a lower wall 7 of the housing 5, and a third surface 24c that faces a discharge hole 26b of a fan 23. The film member 51 includes a first portion 52 attached to the first surface 24a of the heat sink 24, a second portion attached to the second surface of the heat sink 24, and a plurality of third portions 54 attached to the third surface 24c of the heat sink 24.

As shown in FIG. 8, the first portion 52 of the film member 51 has a plate shape that extends in the longitudinal direction of the heat sink 24. The second portion of the film member 51 has a plate shape that extends in the longitudinal direction of the heat sink 24 and has substantially the same shape as the first portion 52.

Each of the plurality of third portions 54 of the film member 51 extends between the first portion 52 and the second portion. The third portion 54 is provided so as to correspond to the closing portion 16 of the housing 5. That is, at least a portion of each third portion 54 faces the closing portion 16 in the flow direction (first direction X) of cooling air. The third portion 54 extends in a direction intersecting (for example, a direction substantially perpendicular to) the flow direction of the cooling air. In this embodiment, an example of the wall portion 41 that blocks the second gap g2 of the heat sink 24 is formed by the third portion 54 of the film member 51.

According to the electronic apparatus 1 having the above-mentioned structure, it is possible to suppress an increase in the temperature of the housing 5, similarly to the first embodiment.

In this embodiment, the wall portion 41 is formed by a portion of the film member 51 attached to the heat sink 24. According to this structure, it is not necessary to provide the bent portion 38 as the wall portion 41 in the heat sink 24. That is, the heat sink 24 can be formed by one kind of fins 27. The heat sink 24 including one kind of fins 27 can contribute to reducing the manufacturing cost of the electronic apparatus 1, as compared to the heat sink 24 including two or more kinds of fins.

### Fourth Embodiment

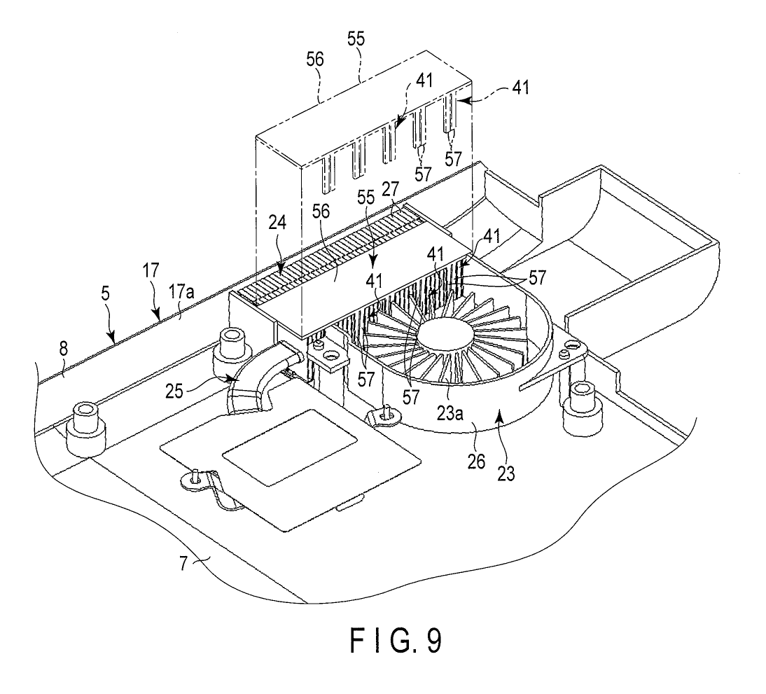

Next, an electronic apparatus 1 according to a fourth embodiment will be described with reference to FIG. 9. In the fourth embodiment, components having the same or similar functions as those in the first to third embodiments are denoted by the same reference numerals and a description thereof will not be repeated. In addition, structures other than the following structures are the same as those in the first embodiment.

As shown in FIG. 9, a heat sink 24 according to this embodiment includes one kind of fins 27, similarly to the third embodiment. In this embodiment, a windshield member 55 is attached to the heat sink 24. The windshield member 55 is made of, for example, a plastic material and has stiffness.

The windshield member 55 has, for example, a comb shape and includes a first portion 56 that is attached to a first surface 24a or a second surface of the heat sink 24 and a plurality of second portions 57 that protrudes from the first portion 56 and is inserted between the fins 27. Each of the second portions 57 is provided so as to correspond to a closing portion 16 of a housing 5. That is, at least a portion of each second portion 57 faces the closing portion 16 in the flow direction (first direction X) of cooling air. The second portion 57 extends in a direction intersecting (for example, a direction substantially perpendicular to) the flow direction of the cooling air.

The second portion 57 of the windshield member 55 is inserted into a second gap g2 of the heat sink 24. In this embodiment, the second portion 57 of the windshield member 55 forms an example of the wall portion 41 that blocks the second gap g2. Instead of the windshield member 55, for example, an elastic member, such as rubber, may be inserted into the second gap g2 of the heat sink 24.

According to the electronic apparatus 1 having the above-mentioned structure, it is possible to suppress an increase in the temperature of the housing 5, similarly to the first embodiment. In addition, in this embodiment, it is possible to reduce the manufacturing cost of the electronic apparatus 1, similarly to the third embodiment.

### Fifth Embodiment

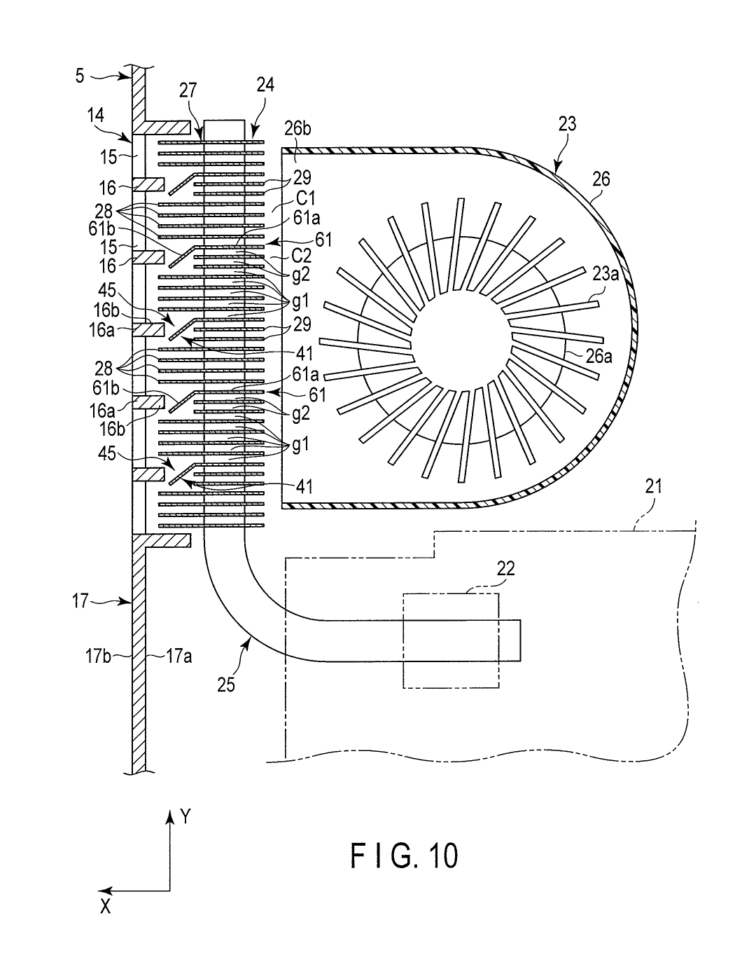

Next, an electronic apparatus 1 according to a fifth embodiment will be described with reference to FIG. 10. In the fifth embodiment, components having the same or similar functions as those in the first to fourth embodiments are denoted by the same reference numerals and a description thereof will not be repeated. In addition, structures other than the following structures are the same as those in the second embodiment.

As shown in FIG. 10, a heat sink 24 according to this embodiment includes first to third fins 28, 29, and 61. The first fin 28 is provided so as to correspond to an opening portion 15 and defines a first gap g1 facing the opening portion 15. The second and third fins 29 and 61 are provided so as to correspond to a closing portion 16 and define a second gap g2 facing the closing portion 16.

As shown in FIG. 10, the second fin 29 is shorter than the first fin 28. The third fin 61 is longer than the second fin 29. An end portion of the third fin 61 is bent so as to be in an area between the second fin 29 and the closing portion 16. In other words, the third fin 61 includes a first portion 61a that is parallel to the second fin 29 and a second portion 61b that is bent from the first portion 61a in the longitudinal direction (second direction Y) of the heat sink 24.

The second portion 61b extends in a direction intersecting the flow direction (first direction X) of cooling air. The second portion 61b is disposed between the second fin 29 and the closing portion 16 and faces the second gap g2 in the flow direction (first direction X) of the cooling air. A gap through which the cooling air can flow is formed between the second portion 61b and the first fin 28.

In this embodiment, the second portion 61b (bent portion) of the third fin 61 forms an example of the wall portion 41 facing the second gap g2. The wall portion 41 is provided in each of a plurality of second areas C2.

In this way, at least a portion of the cooling air flowing through the second gap g2 collides with the wall portion 41. The flow direction of the at least a portion of the cooling air colliding with the wall portion 41 is changed from a direction to the closing portion 16 to a direction to the opening portion 15 (a direction to the first area C1). The cooling air is exhausted from the opening portion 15 to the outside of the housing 5 without substantially colliding with the closing portion 16.

According to the electronic apparatus 1 having the above-mentioned structure, it is possible to suppress an increase in the temperature of the housing 5, similarly to the first embodiment.

In addition, according to this embodiment, it is possible to make cooling air flow into the second gap g2 facing the closing portion 16 while suppressing the collision of the cooling air with the closing portion 16. Therefore, the second and third fins 29 and 61 can contribute to heat dissipation, similarly to the first fin 28. In this structure, since the number of fins 27 contributing to heat dissipation increases, it is possible to improve the heat dissipation efficiency of the heat sink 24, as compared to, for example, the first to fourth embodiments. Therefore, the cooling performance of the electronic apparatus 1 is improved.

### Sixth Embodiment

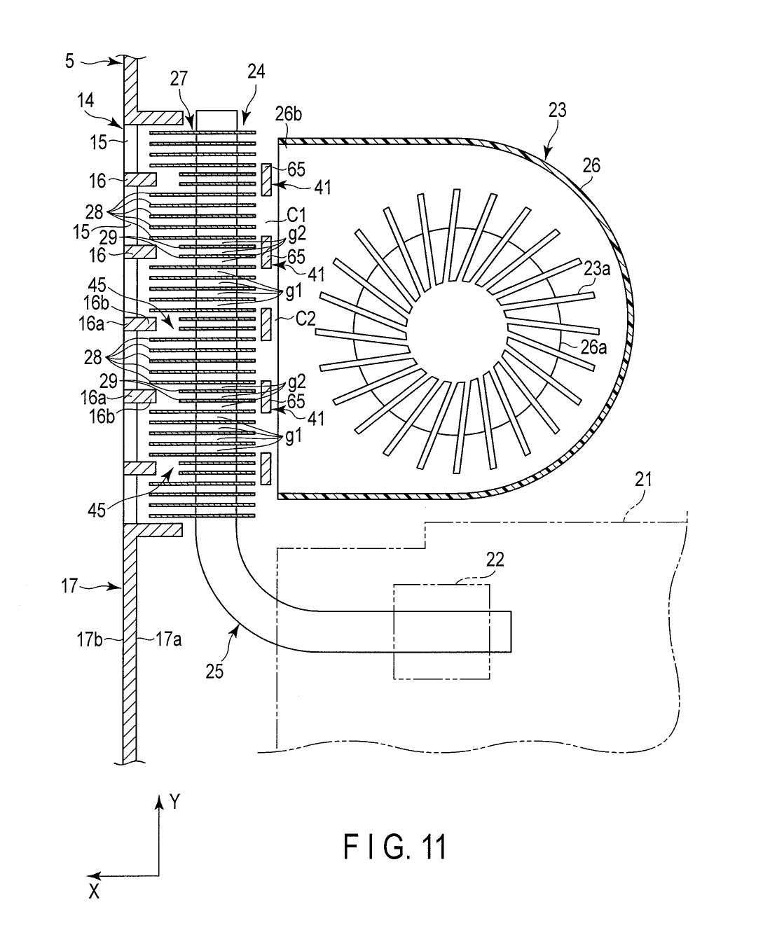

Next, an electronic apparatus 1 according to a sixth embodiment will be described with reference to FIG. 11. In the sixth embodiment, components having the same or similar functions as those in the first to fifth embodiments are denoted by the same reference numerals and a description thereof will not be repeated. In addition, structures other than the following structures are the same as those in the second embodiment.

As shown in FIG. 11, a second fin 29 according to this embodiment does not include the third bent portion 38. A housing 5 includes a plurality of ribs 65 provided between a heat sink 24 and a fan 23. Each of the plurality of ribs 65 is provided so as to correspond to a closing portion 16 of the housing 5. That is, at least a portion of each rib 65 faces the closing portion 16 in the flow direction (first direction X) of cooling air. The rib 65 extends in a direction intersecting (for example, a direction substantially perpendicular to) the flow direction of the cooling air. In this embodiment, the rib 65 forms an example of a wall portion 41 that blocks the second gap g2 of the heat sink 24.

According to the electronic apparatus 1 having the above-mentioned structure, it is possible to suppress an increase in the temperature of the housing 5, similarly to the first embodiment. The heat sink 24 may include one kind of fins 27.

### Seventh Embodiment

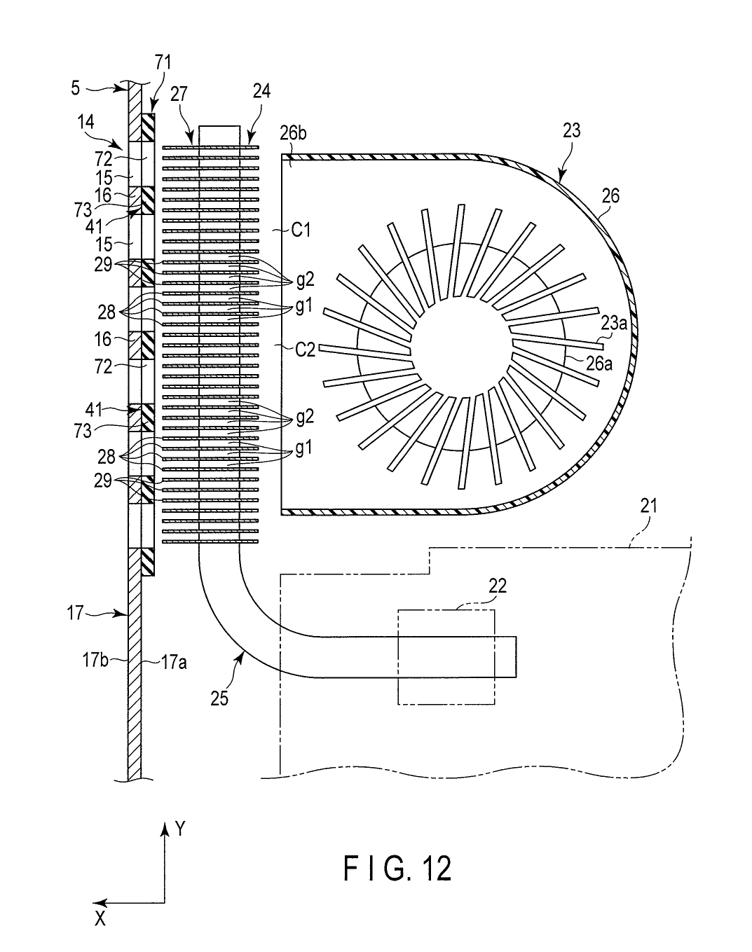

Next, an electronic apparatus 1 according to a seventh embodiment will be described with reference to FIG. 12. In the seventh embodiment, components having the same or similar functions as those in the first to sixth embodiments are denoted by the same reference numerals and a description thereof will not be repeated. In addition, structures other than the following structures are the same as those in the first embodiment.

In this embodiment, an insulator 71 is attached to an inner surface 17a of an outer wall 17 of a housing 5. The insulator 71 is made of, for example, plastic or rubber. The insulator 71 includes opening portions 72 (first portions) corresponding to opening portions 15 of the housing 5 and closing portions 73 (second portions) corresponding to closing portions 16. The closing portion 73 of the insulator 71 faces the closing portion 16 of the housing 5 in the flow direction (first direction X) of cooling air.

In this embodiment, the closing portion 73 of the insulator 71 forms an example of a wall portion 41 that covers the closing portion 16 of the housing 5. At least a portion of the cooling air flowing to the closing portion 16 of the housing 5 collides with the wall portion 41. The flow direction of the at least a portion of the cooling air colliding with the wall portion 41 is changed from a direction to the closing portion 16 to a direction to the opening portion 15 (a direction to the first area C1). Then, the cooling air is exhausted from the opening portion 15 to the outside of the housing 5, without substantially colliding with the closing portion 16.

According to the electronic apparatus 1 having the above-mentioned structure, it is possible to suppress an increase in the temperature of the housing 5, similarly to the first embodiment.

### Eighth Embodiment

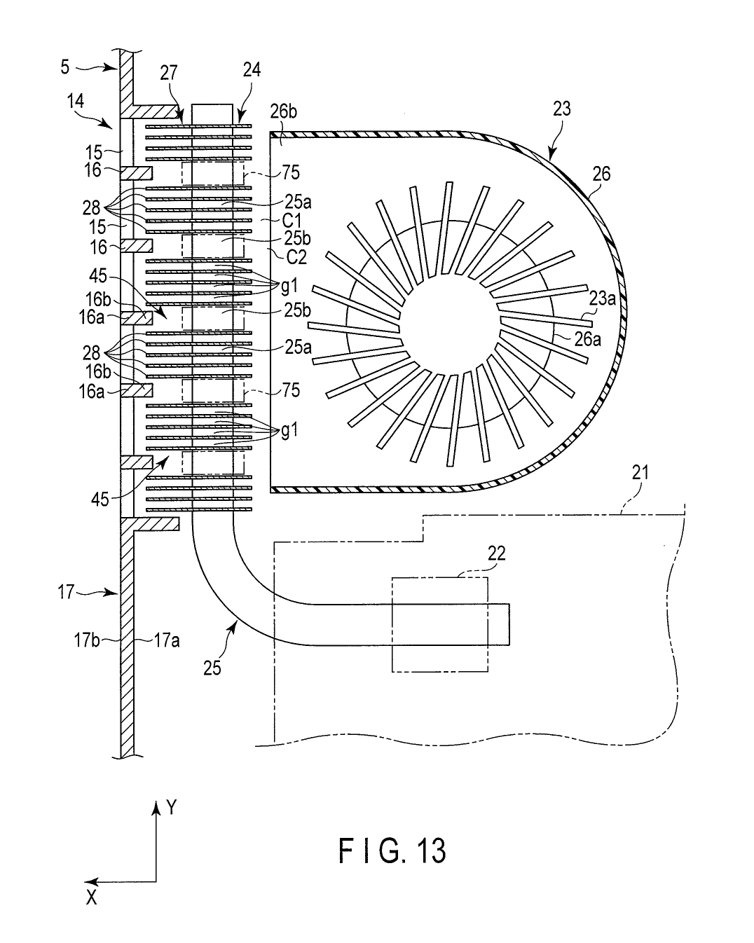

Next, an electronic apparatus 1 according to an eighth embodiment will be described with reference to FIG. 13. In the eighth embodiment, components having the same or similar functions as those in the first to seventh embodiments are denoted by the same reference numerals and a description thereof will not be repeated. In addition, structures other than the following structures are the same as those in the second embodiment.

As shown in FIG. 13, a heat pipe 25 according to this embodiment includes a first portion 25a that is provided in a first area C1 and a second portion 25b that is provided in a second area C2. The first portion 25a faces an opening portion 15 in the flow direction (first direction X) of cooling air. The second portion 25b faces a closing portion 16 in the flow direction (first direction X) of the cooling air.

As shown in FIG. 13, a heat sink 24 according to this embodiment includes fins 28 (first fins) attached to the first portion 25a of the heat pipe 25. The fins 28 are provided in the first area C1. No fin is attached to the second portion 25b of the heat pipe 25. That is, the heat sink 24 does not include any fin in the second area C2. For example, a spacer 75 having a thermal insulation property is provided in the second portion 25b of the heat pipe 25. The spacer 75 is made of, for example, plastic or rubber. The spacer 75 comes into contact with the fin 28 provided in the first area C1 and regulates the position of the fin 28.

According to the electronic apparatus 1 having the above-mentioned structure, it is possible to suppress an increase in the temperature of the housing 5, similarly to the first embodiment.

In addition, in this embodiment, in the heat sink 24, the fin 27 is not provided in the second area C2. Therefore, the cooling air flowing from the fan 23 to the closing portion 16 is not heated to a sufficiently high temperature while passing through the heat sink 24 and collides with the closing portion 16. Therefore, an increase in the temperature of the closing portion 16 is suppressed and thus an increase in the temperature of the housing 5 is suppressed. According to this structure, it is possible to suppress an increase in the temperature of the housing 5, without providing the wall portion 41. The heat sink 24 may include a second fin 29 that has an area less than that of the first fin 28 and is provided in the second area C2.

### Ninth Embodiment

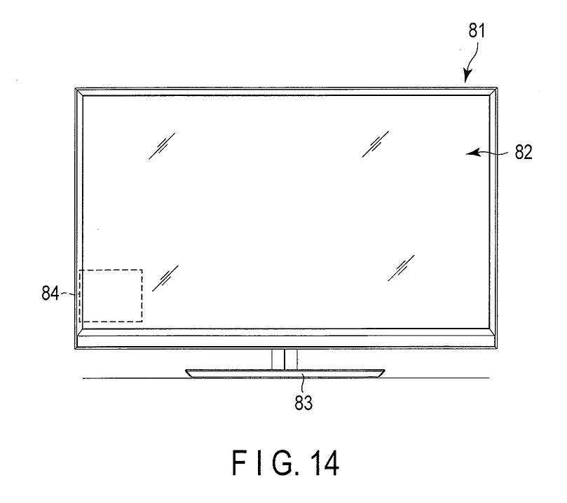

Next, a television 81 according to a ninth embodiment will be described with reference to FIG. 14. In the ninth embodiment, components having the same or similar functions as those in the first to eighth embodiments are denoted by the same reference numerals and a description thereof will not be repeated. In addition, structures other than the following structures are the same as those in the first embodiment.

As shown in FIG. 14, the television 81 includes a display unit 82 and a stand 83. The display unit 82 includes a housing 5. A cooling structure 84 that includes a fan 23, a heat sink 24, and a heat pipe 25 and has the same configuration as that in the first embodiment is provided in the housing 5. The cooling structure 84 may be the same as the cooling structure according to any one of the second to eighth embodiments.

According to the television 81 having the above-mentioned structure, it is possible to suppress an increase in the temperature of the housing 5, similarly to the first embodiment.

According to the first to ninth embodiments, it is possible to suppress an increase in the temperature of the housing 5.

The embodiments are not limited to the above-described embodiments, but the components of the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

Only one first area C1 and only one second area C2 may be provided. The wall portion 41 (windshield portion) may be provided in at least one of the plurality of second areas C2. The wall portion 41 does not necessarily block (cover) the entire gap between the fins 27, but it may block (cover) at least a portion of the gap.

The wall portion 41 is not necessarily provided on the upstream side of the heat sink 24, but may be provided on the downstream side of the heat sink 24. That is, the wall portion 41 according to the first, second, third, and fourth embodiments may be provided in the downstream end portion of the heat sink 24. In the third and fourth embodiments, the film member 51 and the windshield member 55 are attached to the heat sink 24, but the embodiments are not limited thereto. The film member 51 and the windshield member 55 may be attached to the fan 23 or the housing 5. In all of the above-described embodiments, the closing portion 16 may be provided so as to extend in a direction substantially perpendicular to the outer wall 17, as in the second embodiment.

The “portion configured to guide at least a part of air flowing toward the closing portion into the first area” and the “windshield” are not limited to the wall portion 41. The “portion configured to guide at least a part of air flowing toward the closing portion into the first area” and the “windshield” may be any members provided in the housing, or they may be formed by a portion of the housing. The “portion configured to guide at least a part of air flowing toward the closing portion into the first area” and the “windshield” may be any members that affect the flow of cooling air.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An electronic apparatus comprising:
a housing comprising alternating opening portions and closing portions;
a fan in the housing;
first areas in the housing between the fan and the opening portions;
second areas in the housing between the fan and the closing portions;
a circuit board in the housing, the circuit board comprising a heat-generating component;
a heat sink facing the opening portions and the closing portions and comprising fins thermally connected to the heat-generating component; and
guide portions in the second areas, each of the guide portions comprising a wall that covers at least a part of a gap between the fins and configured to guide at least some air flowing from the fan toward at least one of the closing portions into at least one of the first areas.

2. The electronic apparatus of claim 1,
wherein at least a part of one of the guide portions extends in a direction crossing airflow from the fan.

3. (canceled)

4. The electronic apparatus of 1, wherein the wall comprises a film attached to the heat sink.

5. The electronic apparatus of claim 1, wherein the wall comprises a bent end of one of the fins.

6. The electronic apparatus of claim 1,
wherein the fins comprise a first fin in one of the first areas and a second fin in one of the second areas, and
the second fin is smaller than the first fin.

7. The electronic apparatus of claim 6,
wherein at least one of the closing portions extends from the opening portions to an inside of the housing and has a first width in a direction of airflow from the fan and a second width in a direction substantially perpendicular to the direction of airflow from the fan, the first width being greater than the second width.

8. The electronic apparatus of claim 7,
wherein the heat sink comprises a recess facing one of the closing portions, the recess formed by the second fin being smaller than the first fin, and
the one of the closing portions extends toward the recess and is partly in the recess.

9. An electronic apparatus comprising:
a fan comprising a discharge hole;
a housing comprising the fan and alternating opening areas and closing areas, the opening areas and the closing areas facing the discharge hole;
first areas between the fan and the opening areas;
second areas between the fan and the closing areas; and
a heat sink comprising a first fin in each of the first areas and either no fin or a second fin smaller than the first fin in each of the second areas.

10. An electronic apparatus comprising:
a housing comprising alternating opening areas and closing areas;
a fan in the housing;
a heat sink facing the opening areas and the areas and comprising fins;
first areas between the fan and the opening areas;
second areas between the fan and the closing areas; and
a windshield in each of the second areas, the windshield covering at least a part of a gap between the fins in order to differentiate one of the second areas from one of the first areas.

11. The electronic apparatus of claim 1, which is a television.
